(19) United States
(12) Patent Application Publication
(10) Pub. No.: US 2005/0103513 A1
(43) Pub. Date: May 19, 2005

(54) Rf system for an mri apparatus, provided with bead-shaped spacers

(76) Inventor: Dick Van Kempen, Nuenen (NL)

Correspondence Address: Thomas M. Lundin;Philips Intellectual Proterty & Standards, 595 Miner Road, Cleveland, OH, 44143, US

(21) Appl. No.: 10/498,729

(22) PCT Filed: Dec. 18, 2002
(86) PCT No.: PCT/IB02/05627

(30) Foreign Application Priority Data
Dec. 20, 2001 (EP) 01205049.8

(51) Int. Cl. H05K 9/00

(52) U.S. Cl. 174/35 R

(57) ABSTRACT

RF connection cable 2 for interconnecting an RF coil and an RF processing apparatus in an RF system of a medical MRI apparatus. The connection cable 2 is comprised of an outer sleeve 6 enclosing an inner cable comprising RF conductors 24, an inner sleeve 20 and a shield 22. Between the inner sleeve 20 and the outer sleeve 6 a plurality of spacers in the form of large beads 12-i alternating with small beads 14-i are provided. In this way, a very flexible cable is obtained having comparatively low dielectric losses and a low capacitive coupling with the patient.

The invention relates to an RF system for use in a medical MRI apparatus, provided with an RF coil and an RF connection cable connected to said RF coil, which connection cable comprises a number of RF conductors and a number of spacers in the form of drilled-through beads which are provided around said RF conductors and into which the RF conductors extend through the drilled holes in the spacers.

In a medical MRI apparatus, movable RF coils are used for receiving RF signals generated in the tissue of a patient to be examined. Said RF coils are connected, via an RF connection cable, to the RF processing equipment of the MRI apparatus in order to transfer the RF signals induced in the RF coil to said equipment. It is a well-known phenomenon that under certain conditions the signals passing through these RF conductors may be harmful to the patient, in particular cause burns, if the RF connection cable extends close to the skin of the patient.

Swiss patent specification No. 192668 discloses a high-frequency cable wherein an RF conductor is surrounded by a number of bead-shaped spacers, which are spaced apart and rigidly provided on the RF conductor. RF cables for medical MRI applications often require a plurality of conductors, for example four, as a result of which rigidly attaching the spacers to all RF conductors is complicated.

It is an object of the invention to provide an RF connection cable for use in a medical MRI apparatus, which connection cable can be manufactured in a simple manner. For this purpose, the RF system in accordance with the invention is characterized in that the RF connection cable is provided with an outer sleeve, and the bead-shaped spacers have alternately a first dimension and a second dimension.

By providing an outer sleeve, the RF connection cable is made suitable for medical applications and, in particular, any direct contact between a part of the patient's body and the RF conductors is precluded. By providing alternately larger and smaller bead-shaped spacers, the cable obtained is highly flexible as a result of which the ease of handling for the operating staff is improved. A first additional advantage is that RF conductors of a first RF cable cannot get close to RF conductors of another RF cable situated in the vicinity, so that the mutual electrical influence, if any, is small. A second additional advantage is that a part of the volume between the RF conductors and the outer sleeve is formed by air, as a result of which the dielectric losses in the intermediate space are smaller than they would be in a situation where this space is entirely filled with the material of the spacers. In addition, the capacitive coupling between the patient's body and the RF conductors is reduced thereby, so that the risk of so-termed “hot spots” on the patient's body at locations where it contacts the connection cable is reduced, and image artefacts in these locations are counteracted.

In a preferred embodiment of the invention, the bead-shaped spacers are made of polyoxymethylene or of polycarbonate. By virtue thereof, the effect of the above-described low electrical losses, low capacitive coupling and reduction of image artefacts is optimized.

In another embodiment of the invention, the outer sleeve is provided with a smooth outside surface. In addition, the outer sleeve may be made of a biocompatible and biostable synthetic resin. By virtue thereof, the cable can be readily cleaned and is excellently suited for medical applications.

The invention will be described hereinafter with reference to the Figures, wherein corresponding parts are indicated by means of the same reference numerals. In the drawings:

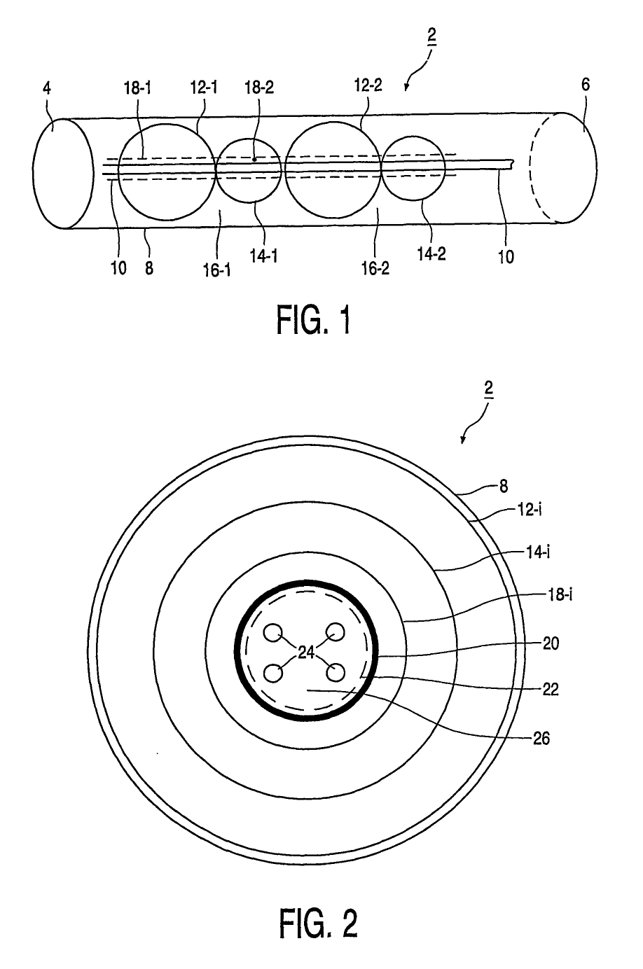

FIG. 1 diagrammatically shows an RF connection cable in accordance with the invention;

FIG. 2 is a cross-sectional view of the RF connection cable in accordance with the invention.

FIG. 1 diagrammatically shows an RF connection cable in accordance with the invention. The RF connection cable 2 is used in an RF system, which RF system is comprised of at least one RF coil, at least one RF connection cable per coil and RF processing equipment. The RF connection cable 2 is used to connect the RF coil (not shown in the Figure) for use in a medical MRI apparatus to the RF processing equipment of said MRI apparatus. To this end, the RF coil is connected to one end 4 and the RF processing equipment (not shown) is connected to the other end 6 with the help of customary connectors.

The outside of the connection cable 2 is formed by an outer sleeve 8 with a smooth outside surface enabling said cable to be readily cleaned. The material from which the outer sleeve 8 is made is preferably biocompatible and biostable, i.e. it must not react with tissue of the patient to be examined or be influenced itself by said tissue. A material which can suitably be used for this purpose is PVC, which can be obtained, in a form suitable for this purpose, from the firm of Adolf Damerius, Schrobenhausen, Germany.

A number of RF conductors, diagrammatically indicated by means of an interrupted line 10, is accommodated in the interior of the RF connection cable 2. Between the RF conductors 10 and the outer sleeve 8, a number of bead-shaped spacers 12-1, 12-2 . . . 12-i . . . are provided having a first external dimension, which is comparatively large in this case, for example 12 mm. Between these spacers 12-i there is provided a number of bead-shaped spacers 14-1, 14-2 . . . 14-i . . . having a different external dimension, which is comparatively small in this case, for example 8 mm. The spacers 14-i and the spacers 12-i are alternately arranged. In this manner, a high degree of flexibility of the RF connection cable 2 is achieved; in addition, a number of cavities 16-1, 16-2 . . . which are not filled with dielectric material are formed in this manner, as a result of which the dielectric losses and undesirable capacitive couplings are reduced. The bead-shaped spacers 12-i and 14-i are all provided with a hole 18-1, 18-2 through which the RF conductors 10 are fed.

The material from which the bead-shaped spacers 12-i and 14-i are made is preferably polyoxymethylene (POM) or polycarbonate, which materials are light and tenacious, i.e. they have a favorable influence on the ease of handling and the strength of the cable, while they do not cause the image produced by the MRI apparatus to be disturbed.

FIG. 2 is a cross-sectional view of the RF connection cable 2 in accordance with the invention. Inside the outer sleeve 8 comparatively large bead-shaped spacers 12-i are provided which alternate with comparatively small bead-shaped spacers 14-1, which spacers are all provided with a hole 18-i. Through the holes an inner cable is provided which is comprised of (from the outside inwards, successively) a synthetic resin (PVC) inner sleeve 20, an electrical RF shield 22 of, for example, copper and four RF conductors 24; the space between the RF conductors 24 within the shield 22 is filled with a suitable material for, inter alia, strain relief, for example a combination of fabric and synthetic resin. The assembly of inner sleeve and all parts accommodated therein is commercially available as an assembled cable from the firm of Ernst & Engbring, Oer-Erkenschwick, Germany.

1. An RF system for use in a medical MRI apparatus, provided with an RF coil and an RF connection cable connected to said RF coil, which RF connection cable comprises a number of RF conductors and a number of spacers in the form of drilled-through beads which are provided around said RF conductors and into which the RF conductors extend through the drilled holes in the spacers, characterized in that an outer sleeve is provided around the spacers, and the bead-shaped spacers have alternately a first dimension and a second dimension.

2. An RF system as claimed in claim 1, wherein the bead-shaped spacers are made of polyoxymethylene or of polycarbonate.

3. An RF system as claimed in claim 1, wherein the outer sleeve is provided with a smooth outside surface.

4. An RF system as claimed in claim 3, wherein the outer sleeve is made of a biocompatible and biostable synthetic resin.

5. An RF connection cable for use in an RF system for a medical MRI apparatus, as defined in claim 1.
